(19) United States
(12) Patent Application Publication
(10) Pub. No.: US 2026/0324460 A1
(43) Pub. Date: Oct. 15, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Yuzeng LIU, Toyonaka Osaka (JP); Masashi ISHII, Ibo Hyogo (JP)

(21) Appl. No.: 19/464,058

(22) Filed: Jan. 29, 2026

Related U.S. Application Data
(63) Continuation of application No. PCT/JP2024/008116, filed on Mar. 4, 2024.

(30) Foreign Application Priority Data
Aug. 7, 2023 (JP) 2023-128628

(51) Int. Cl. H10W 70/60; H10W 90/00; H10W 90/10

(52) U.S. Cl. CPC H10W 70/616; H10W 90/10; H10W 90/754

(57) ABSTRACT

A semiconductor device of an embodiment includes a first circuit board having a plurality of first semiconductor elements, a second circuit board having a plurality of second semiconductor elements, and an output terminal having a plane member, a first extension tab, a second extension tab and a first bridge member. The first extension tab is connected to a first output wiring of the first circuit board. The second extension tab is connected to a second output wiring of the second circuit board. The first extension tab and the second extension tab are connected by the first bridge member.

### CROSS-REFERENCE TO RELATED APPLICATION

This application is a continuation of International Patent Application No. PCT/JP2024/008116, filed Mar. 4, 2024, which designates the United States, and which claims the benefit of priority from Japanese Patent Application No. 2023-128628, filed Aug. 7, 2023, the entire contents of which are incorporated herein by reference.

### FIELD

Embodiments described herein relate generally to a semiconductor device.

### BACKGROUND

Power semiconductor devices designed for power control, including semiconductor devices such as MOSFETs (Metal-Oxide-Semiconductor Field-Effect Transistor) and IGBTs (Insulated Gate Bipolar Transistor), are being developed for a wide range of applications, from power generation and transmission, rotating machinery such as pumps and blowers, to power supply units for communication systems and factories, AC motors for railways, electric vehicles, and household appliances.

Typically, in power semiconductor devices, multiple semiconductor elements provided on a base (substrate) are connected in parallel using bonding wires or terminal boards to handle large amounts of power.

### BRIEF DESCRIPTION OF THE DRAWINGS

FIG. 1 is a schematic perspective diagram of a semiconductor device according to an embodiment;

FIG. 2 is a top view schematic diagram of a semiconductor device according to an embodiment;

FIG. 3 is an equivalent circuit diagram of a semiconductor device according to an embodiment;

FIG. 4 is an equivalent circuit diagram of a semiconductor device according to an embodiment;

FIG. 5 is a schematic diagram of a semiconductor device according to an embodiment;

FIG. 6 is a schematic diagram of a semiconductor device according to an embodiment;

FIG. 7 is a schematic diagram of a semiconductor device according to an embodiment;

FIG. 8 is a schematic diagram of a semiconductor device according to an embodiment;

FIG. 9 is a schematic diagram of a semiconductor device according to an embodiment;

FIG. 10 is a top view schematic diagram of a semiconductor device according to an embodiment;

FIG. 11 is a schematic perspective diagram of an output terminal according to an embodiment;

FIG. 12 is an equivalent circuit diagram of a semiconductor device according to an embodiment;

FIG. 13 is a schematic diagram of a semiconductor device according to an embodiment;

FIG. 14 is a partial schematic diagram of a semiconductor device according to an embodiment;

FIG. 15 is a partial schematic diagram of a semiconductor device according to an embodiment; and

FIG. 16 is a partial schematic diagram of a semiconductor device according to an embodiment.

### DETAILED DESCRIPTION

A semiconductor device of an embodiment includes a first circuit board having a plurality of first semiconductor elements, a second circuit board having a plurality of second semiconductor elements, and an output terminal having a plane member, a first extension tab, a second extension tab and a first bridge member. The first extension tab is connected to a first output wiring of the first circuit board. The second extension tab is connected to a second output wiring of the second circuit board. The first extension tab and the second extension tab are connected by the first bridge member.

Embodiments of the present invention will be described below with reference to the drawings. In the following description, the same reference numerals are used for identical or similar members, and the explanation of a member already explained may be omitted.

### First Embodiment

A first embodiment relates to a semiconductor device includes a first circuit board having a plurality of first semiconductor elements, a second circuit board having a plurality of second semiconductor elements, and an output terminal having a plane member, a first extension tab, a second extension tab and a first bridge member. The first extension tab is connected to a first output wiring of the first circuit board. The second extension tab is connected to a second output wiring of the second circuit board. The first extension tab and the second extension tab are connected by the first bridge member.

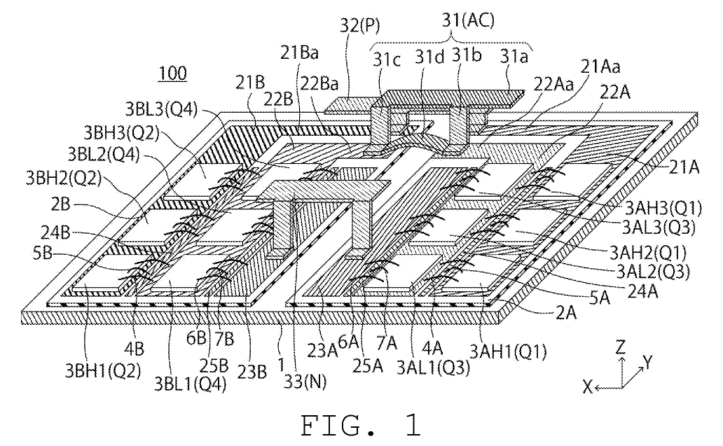

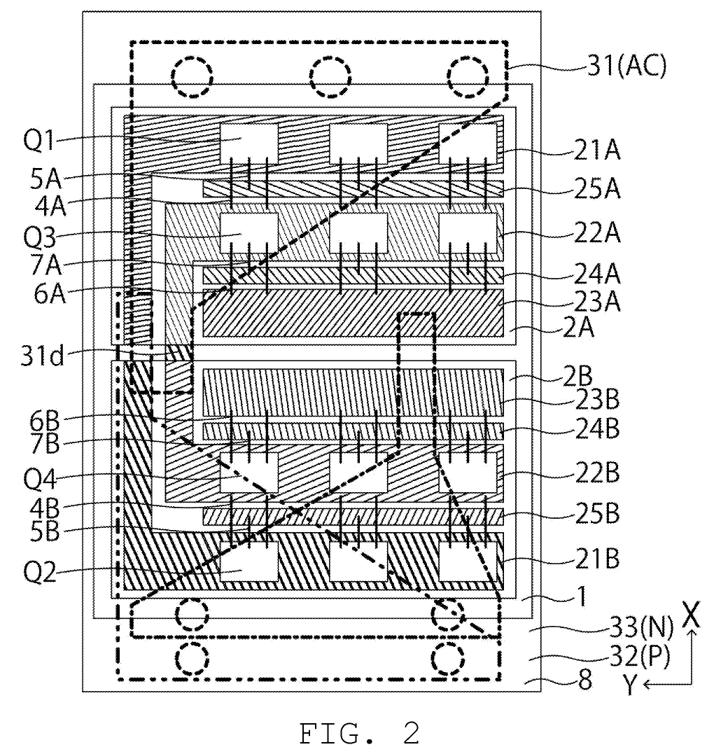

FIG. 1 is a perspective schematic diagram illustrating a semiconductor device 100 of the first embodiment. FIG. 2 is a top view schematic diagram illustrating the semiconductor device 100 according to the first embodiment. In the diagrams of FIGS. 1 and 2, members such as gate terminals are omitted. In the diagram of FIG. 1, some members (for example, terminals) are partially illustrated.

A first direction (X direction) intersects and is preferably perpendicular to a second direction (Y direction). The first direction (X direction) intersects and is preferably perpendicular to a third direction (Z direction). The second direction (Y direction) and the third direction (Z direction) intersect and is preferably perpendicular.

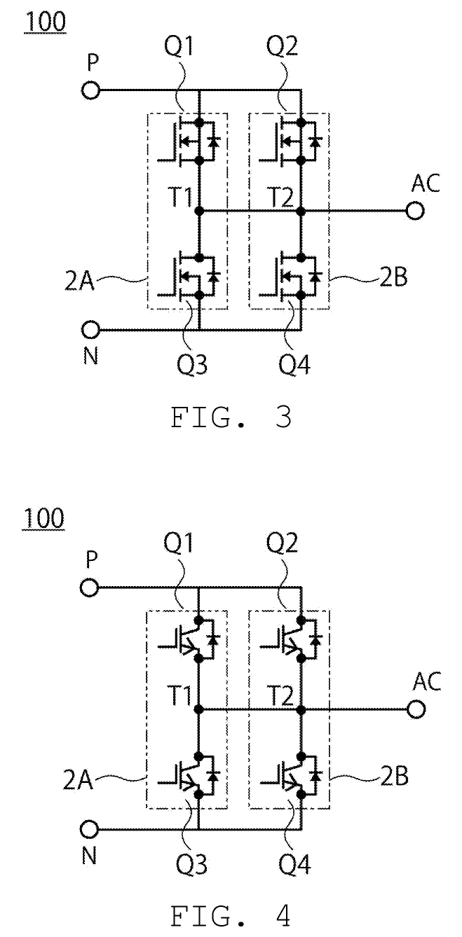

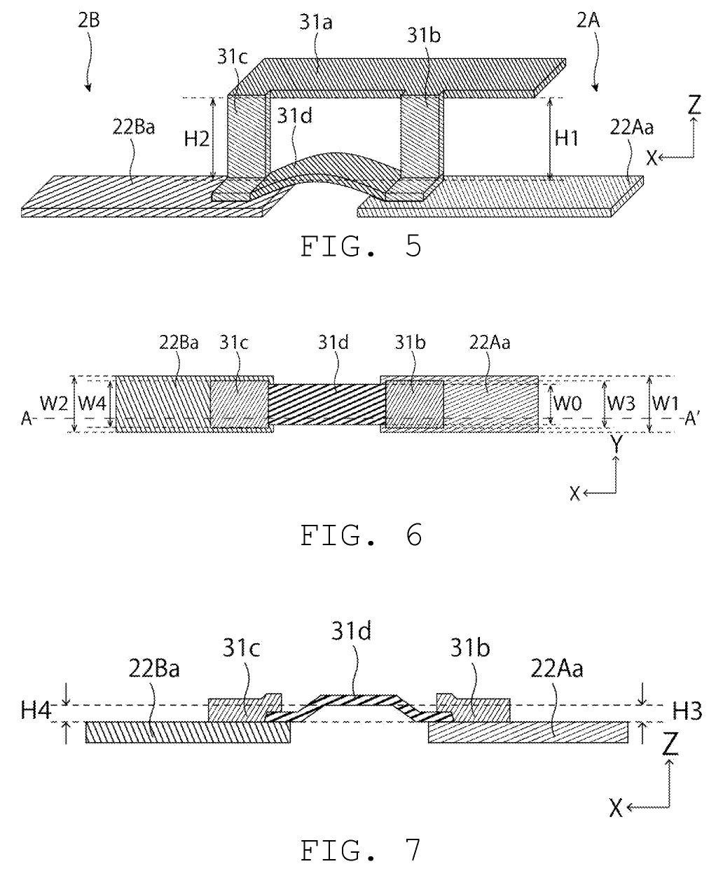

FIGS. 3 and 4 are equivalent circuit diagrams of the semiconductor device 100 according to the first embodiment. FIGS. 5, 6, 7, 8, and 9 are diagrams illustrating a portion of the semiconductor device 100 according to the first embodiment with some members removed. FIGS. 7, 8, and 9 are cross-sectional views along line AA' in FIG. 6.

The semiconductor device 100 according to the first embodiment is a power semiconductor module. As shown in FIG. 4, the semiconductor device 100 according to the first embodiment is a so-called "2 in 1" type module that can constitute a half-bridge circuit with one module. The semiconductor device 100 has three half-bridge units connected in parallel. For example, by using three of the semiconductor devices 100 according to the first embodiment, a three-phase inverter circuit can be constituted. For example, a semiconductor device mounted with three circuits of the semiconductor device 100 according to the first embodiment may include a three-phase inverter circuit.

FIG. 3 is an equivalent circuit diagram of the semiconductor device 100 using MOSFETs for semiconductor elements Q1 to Q4.

FIG. 4 is an equivalent circuit diagram of the semiconductor device 100 using IGBTs for the semiconductor elements Q1 to Q4.

Although the semiconductor device 100 is described using an n-channel MOSFET or an npn-type IGBT as examples, the semiconductor elements Q1 to Q4 may be p-channel MOSFETs or pnp-type IGBTs. A base of the IGBT is conveniently represented as a gate.

As shown in FIGS. 3 and 4, the semiconductor device 100 has a positive terminal P (a first terminal 32), an AC output terminal AC (an output terminal 31), and a negative terminal N (a second terminal 33).

The semiconductor device 100 includes a plurality of high-side semiconductor elements (a first semiconductor element Q1, a second semiconductor element Q2) and a plurality of low- side semiconductor elements (a semiconductor element Q3, a semiconductor element Q4). FIG. 1 illustrates an example configuration in which the first semiconductor element Q1, the second semiconductor element Q2, the semiconductor element Q3, and the semiconductor element Q4 each comprise three semiconductor elements.

The high-side semiconductor elements are connected in parallel. The low-side semiconductor elements are connected in parallel. The high-side semiconductor elements connected in parallel and the low-side semiconductor elements connected in parallel are connected in series.

As shown in FIGS. 1 and 2, the semiconductor device 100 includes a substrate 1, a first circuit board 2A, a second circuit board 2B, a first semiconductor element 3AH1, a first semiconductor element 3AH2, a first semiconductor element 3AH3, a semiconductor element 3AL1, a semiconductor element 3AL2, a semiconductor element 3AL3, a second semiconductor element 3BH1, a second semiconductor element 3BH2, a second semiconductor element 3BH3, a semiconductor element 3BL1, a semiconductor element 3BL2, a semiconductor element 3BL3, a wiring(s) 4A, a wiring(s) 4B, a wiring(s) 5A, a wiring(s) 5B, a wiring(s) 6A, a wiring(s) 6B, a wiring(s) 7A, a wiring(s) 7B, an outer package material 8, the output terminal 31 (AC), the first terminal 32 (P), and the second terminal 33 (N).

The substrate 1 supports the first circuit board 2A and the second circuit board 2B. For example, the substrate 1 is a member with high heat dissipation properties, such as a metal plate. As the substrate 1, a Cu plate or an AlSiC plate is preferable.

The first circuit board 2A is provided on the substrate 1. The first circuit board 2A is a board on which a conductive layer 21A, a conductive layer 22A, a conductive layer 23A, a conductive layer 24A, and a conductive layer 25A are provided on an insulating substrate. The conductive layer 21A, the conductive layer 22A, the conductive layer 23A, the conductive layer 24A, and 2the conductive layer 5A are composed of a conductive material such as Cu, for example.

The second circuit board 2B is provided on the substrate 1. The second circuit board 2B is a board on which a conductive layer 21B, a conductive layer 22B, a conductive layer 23B, a conductive layer 24B, and a conductive layer 25B are provided on an insulating substrate. The conductive layer 21B, the conductive layer 22B, the conductive layer 23B, the conductive layer 24B, and the conductive layer 25B are composed of a conductive material such as Cu, for example.

Preferably, the first circuit board 2A and the second circuit board 2B are configured symmetrically with respect to a virtual line passing through the center of the substrate 1, dividing the substrate 1 into two parts. The wiring configuration of the first circuit board 2A and the second circuit board 2B shown in FIG. 1 or the like is just one example and is not limited to the configurations described in the specification.

The first semiconductor element 3AH1, the first semiconductor element 3AH2, the first semiconductor element 3AH3, the semiconductor element 3AL1, the semiconductor element 3AL2, the semiconductor element 3AL3, the second semiconductor element 3BH1, the second semiconductor element 3BH2, the second semiconductor element 3BH3, the semiconductor element 3BL1, the semiconductor element 3BL2, and the semiconductor element 3BL3 are MOSFETs or IGBTs.

The first semiconductor element 3AH1, the first semiconductor element 3AH2, the first semiconductor element 3AH3, the semiconductor element 3AL1, the semiconductor element 3AL2, and the semiconductor element 3AL3 are provided on the first circuit board 2A. In this specification, the first semiconductor element 3AH1, the first semiconductor element 3AH2, and the first semiconductor element 3AH3 may be collectively referred to as the first semiconductor device Q1. The semiconductor element 3AL1, the semiconductor element 3AL2, and the semiconductor element 3AL3 may be collectively referred to as the semiconductor element Q3.

Preferably, the first semiconductor element 3AH1, the first semiconductor element 3AH2, the first semiconductor

element 3AH3, the semiconductor element 3AL1, the semiconductor element 3AL2, the semiconductor element 3AL3, the second semiconductor element 3BH1, the second semiconductor element 3BH2, the second semiconductor element 3BH3, the semiconductor element 3BL1, the semiconductor element 3BL2, and the semiconductor element 3BL3 are semiconductor elements having the same configuration or characteristics considering without individual differences.

The first semiconductor element 3AH1, the first semiconductor element 3AH2, and the first semiconductor element 3AH3 are high-side semiconductor elements provided on the first circuit board 2A. The source electrode or emitter electrode of each of first semiconductor element 3AH1, the first semiconductor element 3AH2, and the first semiconductor element 3AH3 is directed toward the side of the conductive layer 21A and is provided on the conductive layer 21A.

The semiconductor element 3AL1, the semiconductor element 3AL2, and the semiconductor element 3AL3 are low-side semiconductor elements provided on the first circuit board 2A. The drain electrode or collector electrode of each of the semiconductor element 3AL1, the semiconductor element 3AL2, and the semiconductor element 3AL3 is directed toward the side of the conductive layer 22A and is provided on the conductive layer 22A.

The second semiconductor element 3BH1, the second semiconductor element 3BH2, the second semiconductor element 3BH3, the semiconductor element 3BL1, the semiconductor element 3BL2, and the semiconductor element 3BL3 are provided on the second circuit board 2B. In this specification, the second semiconductor element 3BH1, the second semiconductor element 3BH2, and the second semiconductor element 3BH3 may be collectively referred to as the second semiconductor device Q2. The semiconductor element 3BL1, the semiconductor element 3BL2, and the semiconductor element 3BL3 may be collectively referred to as the semiconductor element Q4.

The second semiconductor element 3BH1, the second semiconductor element 3BH2, and the second semiconductor element

3BH3 are high-side semiconductor elements provided on the second circuit board 2B. The source electrode or emitter electrode of each of second semiconductor element 3BH1, the second semiconductor element 3BH2, and the second semiconductor element 3BH3 is directed toward the side of conductive layer 21B and is provided on conductive layer 21B.

The semiconductor element 3BL1, the semiconductor element 3BL2, and the semiconductor element3BL3 are low-side semiconductor elements provided on the second circuit board 2B. The drain electrode or collector electrode of each of the semiconductor elements 3BL1, the semiconductor element3 BL2, and the semiconductor element3BL3 is directed toward the side of conductive layer 22B and is provided on conductive layer 22B.

The wiring 4A is a wire that connects the source electrode of the first semiconductor element Q1 on the high side and the conductive layer 22A. For example, the wiring 4A is an aluminum bonding wire.

The wiring 4B is a wire that connects the source electrode of the second semiconductor element Q2 on the high side and the conductive layer 22B. For example, the wiring 4B is an aluminum bonding wire.

The wiring 5A is a wire that connects the gate electrode of the first semiconductor element Q1 on the high side and the conductive layer 24A. For example, the wiring 5A is an aluminum bonding wire.

The wiring 5B is a wire that connects the gate electrode of the second semiconductor element Q2 on the high side and the conductive layer 24B. For example, the wiring 5B is an aluminum bonding wire.

The wiring 6A is a wire that connects the source electrode of the semiconductor element Q3 on the low side and the conductive layer 23A. For example, the wiring 6A is an aluminum bonding wire.

The wiring 6B is a wire that connects the source electrode of the semiconductor element Q4 on the low side and the conductive layer 23B. For example, the wiring 6B is an aluminum bonding wire.

The wiring 7A is a wire that connects the gate electrode of the semiconductor element Q3 on the low side and the conductive layer 25A. For example, the wiring 7A is an aluminum bonding wire.

The wiring 7B is a wire that connects the gate electrode of the semiconductor element Q4 on the low side and the conductive layer 25B. For example, the wiring 7B is an aluminum bonding wire.

The outer package material 8 is provided around the substrate 1, the first circuit board 2A, and the second circuit board 2B. The outer package material 8 is an example of a frame. A part of the outer package material 8 is provided on the substrate 1.

The outer package material 8 has a function of protecting the first semiconductor element Q1, the second semiconductor element Q2, the semiconductor element Q3, the semiconductor element Q4, the first circuit board 2A, and the second circuit board 2B.

Cutouts or the like for fixing terminals such as the output terminal 31, the first terminal 32, and the second terminal 33 are provided in the outer package material 8.

The outer package material 8 includes a resin. For example, the resin of the outer package material 8 is a polyphenylene sulfide resin (PPS resin). For example, the outer package material 8 is composed of a polyphenylene sulfide resin (PPS resin).

A lid (not shown in the figure) is provided on the upper part of the outer package material 8. The lid has a function of protecting the first semiconductor element Q1, the second semiconductor element Q2, the substrate 1, and the others.

The conductive layer 21A is a wiring layer provided on the first circuit board 2A. The first semiconductor element Q1 is arranged in parallel in the second direction (Y-direction) on the conductive layer 21A. The first semiconductor element Q1 is connected to the conductive layer 21A via a solder layer or a sintered junction layer (a conductive junction layer formed by sintering of Ag paste, etc.). The conductive layer 21A has a first power wiring 21Aa that extends toward the second circuit board 2B.

The conductive layer 21B is a wiring layer provided on the second circuit board 2B. The second semiconductor element Q2 is arranged in parallel in the second direction (Y-direction) on the conductive layer 21B. The second semiconductor element Q2 is connected to the conductive layer 21B via a solder layer or a sintered junction layer. The conductive layer 21B has a second power wiring 21Ba that extends toward the first circuit board 2A.

The first power wiring 21Aa and the second power wiring 21Ba are electrically connected through the first terminal 32. Preferably, the first power wiring 21Aa and the second power wiring 21Ba are parallel to each other. Preferably, the first power wiring 21Aa and the second power wiring 21Ba align in a straight line.

The conductive layer 22A is a wiring layer provided on the first circuit board 2A. The semiconductor device Q3 is arranged in parallel in the second direction (Y-direction) on the conductive layer 22A. The semiconductor device Q3 is connected to the conductive layer 22A via a solder layer or a sintered junction layer. The conductive layer 22A is connected to the wiring 4A which electrically connects to the first semiconductor element Q1. The conductive layer 22A has a first output wiring 22Aa that extends toward the second circuit board 2B.

The conductive layer 22B is a wiring layer provided on the second circuit board 2B. The semiconductor device Q4 is arranged in parallel in the second direction (Y-direction) on the conductive layer 22B. The semiconductor device Q4 is connected to the conductive layer 22B via a solder layer or a sintered junction layer. The conductive layer 22B is connected to the wiring 4B which electrically connects to the second semiconductor element Q2. The conductive layer 22B has a second output wiring 22Ba that extends toward the first circuit board 2A.

The first output wiring 22Aa and the second output wiring 22Ba are electrically connected through the output terminal 31. Preferably, the first output wiring 22Aa and the second output wiring 22Ba are parallel to each other. Preferably, the first output wiring 22Aa and the second output wiring 22Ba align in a straight line.

The conductive layer 23A is a wiring layer provided on the first circuit board 2A. The conductive layer 23A is connected to the wiring 6A which electrically connects to the semiconductor element Q3 on the low side.

The conductive layer 23B is a wiring layer provided on the second circuit board 2B. The conductive layer 23B is connected to the wiring 6B which electrically connects to the semiconductor element Q4 on the low side.

The conductive layer 23A and the conductive layer 23B are electrically connected through the second terminal 33.

The conductive layer 24A is a wiring layer provided on the first circuit board 2A. The conductive layer 24A is connected to the wiring 5A which electrically connects to the first semiconductor element Q1 on the high side.

The conductive layer 24B is a wiring layer provided on the second circuit board 2B. The conductive layer 24B is connected to the wiring 5B which electrically connects to the second semiconductor element Q2 on the high side.

The conductive layer 25A is a wiring layer provided on the first circuit board 2A. The conductive layer 25A is connected to the wiring 7A which electrically connects to the semiconductor element Q3 on the low side.

The conductive layer 25B is a wiring layer provided on the second circuit board 2B. The conductive layer 25B is connected to the wiring 7B which electrically connects to the semiconductor element Q4 on the low side.

The output terminal 31 is provided on the first circuit board 2A and the second circuit board 2B. The output terminal 31 spans the first circuit board 2A and the second circuit board 2B. The output terminal 31 connects the first output wiring 22Aa and the second output wiring 22Ba. The output terminal 31 electrically connects the first output wiring 22Aa and the second output wiring 22Ba. Preferably, the output terminal 31 directly and electrically connects the first output wiring 22Aa and the second output wiring 22Ba.

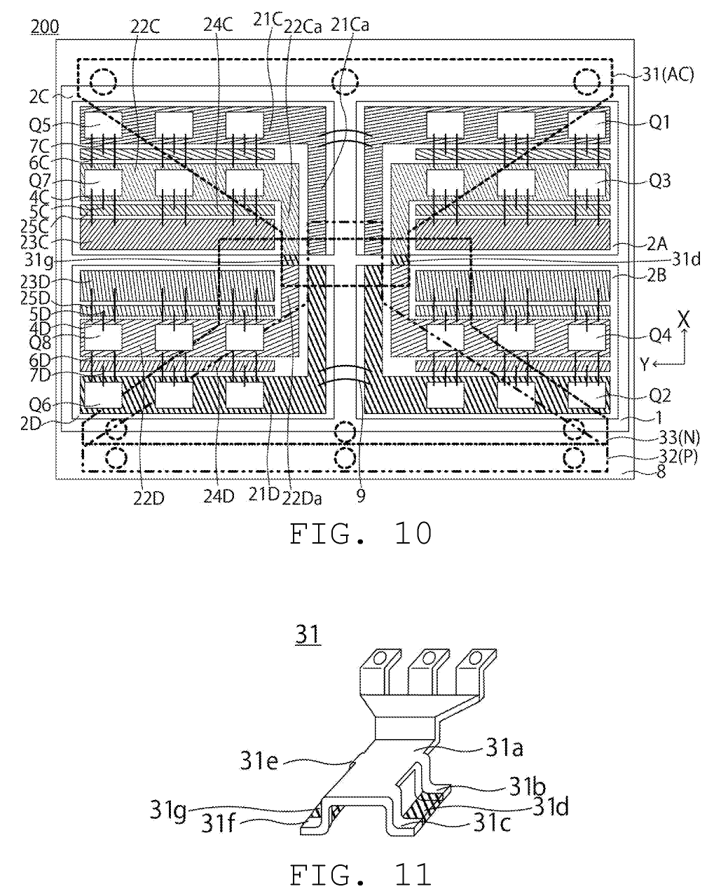

As shown in FIGS. 1 and FIG. 5, the output terminal 31 includes a plane member 31a which is not in direct contact with the first bridge member 31d, a first extension tab 31b, a second extension tab 31c, and a first bridge member 31d. The specific structure of the output terminal 31 is illustrated in the schematic diagram of FIG. 11 of the second embodiment. The output terminal 31 has an opening such as a screw hole in a portion connected to the outside.

The plane member 31a is connected to the first extension tab 31b and the second extension tab 31c. The first extension tab 31b and the second extension tab 31c extend from the plane member 31a.

The first extension tab 31b is connected to the first output wiring 22Aa. The first extension tab 31b is preferably in direct contact with the first output wiring 22Aa. Two bend structures are included between the plane member 31a and the connection portion of the first extension tab 31b and the first output wiring 22Aa.

The second extension tab 31c is connected to the second output wiring 22Ba. The second extension tab 31c is preferably in direct contact with the second output wiring 22Ba. Two bend structures are included between the plane member 31a and the connection portion of the second extension tab 31c and the second output wiring 22Ba.

The first bridge member 31d connects the first extension tab 31b and the second extension tab 31c. The first bridge member 31d is provided between the first extension tab 31b and the second extension tab 31c. The first bridge member 31d is in contact directly and electrically with the first extension tab 31b and the second extension tab 31c. The first bridge member 31d electrically connects T1 and T2 in the equivalent circuit diagrams shown in FIGS. 3 and 4.

The first extension tab 31b has a folded shape at the connection portion with the plane member 31a and the connection portion with the first output wiring 22Aa. The second extension tab 31c has a folded shape at the connection portion with the plane member 31a and the connection portion with the second output wiring 22Ba. Preferably, a path from the first output wiring 22Aa to the second output wiring 22Ba through the first bridge member 31d does not pass through the folded shape portions of the first extension tab 31b and the second extension tab 31c.

Preferably, the first bridge member 31d is a single conductor connecting the first extension tab 31b and the second extension tab 31c. For example, the first bridge member 31d is a flat plate or a ribbon-shaped conductor with some bends, preferably.

Preferably, the first bridge member 31d is a conductor that is not divided into two or more conductors connecting the first extension tab 31b and the second extension tab 31c.

Since the first bridge member 31d is not a thin wire such as a bonding wire, there is a lower probability of it being cut when fixing the output terminal 31 to the first circuit board 2A and the second circuit board 2B, resulting in higher reliability.

The source electrode, which is the output side of the first semiconductor element Q1, and the source electrode, which is the output side of the second semiconductor element Q2, are connected by the first bridge member 31d (connection form 1). When the first bridge member 31d does not exist, the source electrode of the first semiconductor element Q1 and the source electrode of the second semiconductor element Q2 are connected via the first extension tab 31b, the plane member 31a, and the second extension tab 31c (connection form 2). The connection form 1 allows the source electrodes to be connected by the first bridge member 31d without passing through four bend portions from the first extension tab 31b through the plane member 31a to the second extension tab 31c. The semiconductor device 100 has connection form 1, which is a shorter wiring path than connection form 2. By connecting the source electrodes of the first semiconductor element Q1 and the second semiconductor element Q2 with the shorter wiring path of connection form 1, the circuit boards can be connected with low inductance wiring between the source electrodes.

As shown in the schematic diagram of FIG. 5, the height (distance from the surface of the first output wiring 22Aa or the second output wiring 22Ba in the Z direction) of the first bridge member 31d is significantly lower than the height H1 of the first extension tab 31b and the height of the second extension tab 31c. By making the height of the first bridge member 31d lower than the heights of the first extension tab 31b and the second extension tab 31c, the path between the sources via the first bridge member 31d can be connected with shorter wiring.

In a semiconductor device without connection form 1, the inductance of the wiring connecting the source electrodes of the first semiconductor element Q1 and the second semiconductor element Q2 becomes larger. Due to individual differences in the semiconductor devices included in the semiconductor device 100, variations in source potential occur in each semiconductor device (the first semiconductor element 3AH1, the first semiconductor element 3AH2, and the first semiconductor element 3AH3) in the first semiconductor element Q1, variations in source potential occur in each semiconductor device (the second semiconductor element 3BH1, the second semiconductor element 3BH2, and the second semiconductor element 3BH3) in the second semiconductor element Q2, and variations in source potential between the first semiconductor element Q1 and the second semiconductor element Q2 become more likely to occur.

Since this source potential serves as a reference for the gate, fluctuation may be added to the gate signal due to potential fluctuations. The fluctuation added to the gate signal can cause the semiconductor device to oscillate.

The semiconductor device including connection form 1 connects the sources between each board with low inductance, suppressing the aforementioned three source potential variations. As a result, fluctuation in the gate signal is reduced or eliminated, preventing oscillation.

Terminals used in semiconductor modules are ultrasonically bonded to conductive layers. The output terminal 31 requires a certain extension tab length for stress relief during ultrasonic bonding, making it difficult to shorten the extension tab length of the output terminal 31.

When bonding wires are formed between the extension tabs of the output terminal 31, the bonding wires and the output terminal 31 become too close together. This makes the bonding wires prone to being cut during ultrasonic bonding of the output terminal 31. Positional misalignment during fabrication of the semiconductor device 100 can further increase the likelihood of the bonding wires between the extension tabs of the output terminal 31 being cut during ultrasonic bonding.

Moreover, unlike a thin wire like a bonding wire, the first bridge member 31d is a thick conductor. Inductance of the thick first bridge 31d is lower than that of a thin wire like a bonding wire. This allows for low-inductance wiring between the source electrodes. The first bridge member 31d benefits from both inductance reduction due to shortened wiring paths and inductance reduction due to its thick construction.

For embodiments of the semiconductor device 100, adding the first bridge member 31d allows for connection between the sources with low-inductance wiring without requiring shape modification of the existing AC output terminal bridge part. The advantage of the output terminal 31A in this embodiment is that it does not require overall shape modification of the AC output terminal to add the first bridge member 31d. Therefore, the output terminal 31 with the first bridge member 31d can be adopted for various semiconductor modules with circuit configurations other than those illustrated.

For example, even when the second extension tab 31c (or the first extension tab 31b) is removed, the sources of the first semiconductor element Q1 and the second semiconductor element Q2 can be connected with low inductance. However, both currents output from the sources of the first semiconductor element Q1 and the second semiconductor element Q2 flow through the first extension tab 31b. Removing the second extension tab 31c may necessitate a significant re-design of the output terminal 31 design from the perspective of current capacity of the first extension tab 31b, therefore, the output terminal 31 with the second extension tab 31c is preferable.

The first terminal 32 is provided on the first circuit board 2A and the second circuit board 2B. The first terminal 32 spans the first circuit board 2A and the second circuit board 2B. The first terminal 32 connects the first power wiring 21Aa and the second power wiring 21Ba. The first terminal 32 electrically connects the first power wiring 21Aa and the second power wiring 21Ba. Preferably, the first terminal 32 directly and electrically connect the first power wiring 21Aa and the second power wiring 21Ba.

The second terminal 33 is provided on the first circuit board 2A and the second circuit board 2B. The second terminal 33 spans the first circuit board 2A and the second circuit board 2B. The second terminal 33 connects the conductive layer 23A and the conductive layer 23B. The second terminal 33 electrically connects the conductive layer 23A and the conductive layer 23B. Preferably, the second terminal 33 directly and electrically connect the conductive layer 23A and the conductive layer 23B.

FIG. 6 shows a schematic diagram indicating the width of each member. The wiring width of the first bridge member 31d is represented by W0. The wiring width of the first output wiring 22Aa is represented by W1. The wiring width of the second output wiring 22Ba is represented by W2. The wiring width of the first extension tab 31b is represented by W3. The wiring width of the second extension tab 31c is represented by W4.

The wiring width W0 of the first bridge member 31d is the length of the first bridge member 31d in a direction perpendicular to the direction from the first extension tab 31b to the second extension tab 31c as viewed from above, as shown in the schematic diagram of FIG. 2. The wiring width W0 does not take into account the portion where the first extension tab 31b and the first bridge member 31d overlap in the Z direction.

The maximum value of the wiring width W0 of the first bridge member 31d is preferably 120% or less, and 100% or more of the average value of the wiring width W0.

The minimum value of the wiring width W0 of the first bridge member 31d is preferably 80% or more and 100% or less of the average value of the wiring width W0.

The wiring width W1 of the first output wiring 22Aa is the average width of the first output wiring 22Aa, including the portion where the first output wiring 22Aa and the first extension tab 31b are connected.

From the viewpoint of reducing inductance between the sources, the wiring width W0 of the first bridge member 31d is preferably 60% or more and 100% or less of the wiring width W1 of the first output wiring 22Aa, and more preferably 65% or more and 95% or less.

The wiring width W2 of the second output wiring 22Ba is the average width of the second output wiring 22Ba, including the portion where the second output wiring 22Ba and the second extension tab 31c are connected.

From the viewpoint of reducing inductance between the sources, the wiring width W0 of the first bridge member 31d is preferably 60% or more and 100% or less of the wiring width W2 of the second output wiring 22Ba, and more preferably 65% or more and 95% or less.

From the viewpoint of reducing inductance between the sources, the wiring width W3 of the first extension tab 31b (the width direction of the first extension tab 31b is along with a width direction of the width W1) is preferably 70% or more and 100% or less of the wiring width W1, and more preferably 75% or more and 95% or less.

From the viewpoint of reducing inductance between the sources, the wiring width W4 of the second extension tab 31c (the width direction of the second extension tab 31c is along with a width direction of the width W2) is preferably 70% or more and 100% or less of the wiring width W2, and more preferably 75% or more and 95% or less.

From the viewpoint of reducing inductance between the sources, the wiring width W0 of the first bridge member 31d is preferably 60% or more and 100% or less of the wiring width W1 of the first output wiring 22Aa and 60% or more and 100% or less of the wiring width W2 of the second output wiring 22Ba. For the same viewpoint, the wiring width W0 of the first bridge member 31d is preferably 65% or more and 95% or less of the wiring width W1 of the first output wiring 22Aa and 65% or more and 95% or less of the wiring width W2 of the second output wiring 22Ba.

Preferably, the longitudinal direction of the first bridge member 31d is in the direction from the first circuit board 2A to the second circuit board 2B. Preferably, the width direction of the first bridge member 31d is in the same direction as the width direction of the first output wiring 22Aa. Preferably, the width direction of the first bridge member 31d is in the same direction as the width direction of the second output wiring 22Ba. When the width direction of the second output wiring 22Ba deviates significantly, the wire length will increase, which is not preferable. Preferably, the width direction of the first bridge member 31d and the width direction of the first output wiring 22Aa are generally aligned. The angle difference between the width direction of the first bridge member 31d and the width direction of the first output wiring 22Aa is preferably 0° or more and 10° or less, and more preferably 0° or more and 5° or less. For the parallelism of other members, an angle deviation is allowed, and the angle difference is preferably 0° or more and 10° or less, and more preferably 0° or more and 5° or less.

FIGS. 7 and 8 are schematic diagrams showing cross-sectional views of a configuration where a ribbon such as aluminum is used for the first bridge member 31d. The first bridge member 31d is ribbon-shaped. The shape of the output terminal 31 when a ribbon is used is not limited to the shapes shown in FIGS. 7 and 8. The shape of the output terminal 31 when a ribbon is used can be changed depending on the thickness of the member and the conditions during ultrasonic bonding. When a ribbon is used for the first bridge member 31d, the element primarily constituting the plane member 31a (the metal element with the highest ratio contained in the plane member 31a) is preferably different from the element primarily constituting the first bridge member 31d (the metal element with the highest ratio contained in the first bridge member 31d). Preferably, Cu is the element primarily constituting the plane member 31a. Preferably, the element primarily constituting the first bridge member 31d is one or more elements (e.g., Al) other than Cu.

By arranging an output terminal 31 without the first bridge member 31d on a ribbon and integrating the ribbon and the output terminal 31 by ultrasonic bonding, the first output wiring 22Aa is joined to the output terminal 31, and the second output wiring 22Ba is joined to the output terminal 31. After bonding, the non-bonded portion of the ribbon forms the first bridge member 31d. By applying ultrasonic waves and pressure, gaps between the first extension tab 31b and the first output wiring 22Aa with the ribbon sandwiched therebetween and gaps between the second extension tab 31c and the second output wiring 22Ba with the ribbon sandwiched therebetween are eliminated. The output terminal with the first bridge member 31d is firmly joined to the first output wiring 22Aa and the second output wiring 22Ba.

During ultrasonic bonding, pressure is applied with a capillary to the portions where the first extension tab 31b and the second extension tab 31c overlap the ribbon, partially deforming the first extension tab 31b and the second extension tab 31c for bonding. The thickness of the first bridge member 31d (ribbon thickness) is preferably the same as the depth to which the capillary is pressed into the member. The thickness of the first bridge member 31d (ribbon thickness) is preferably 70% or more and 130% or less, and more preferably 85% or more and 115% or less, compared to the thickness of the non-bonded portions of the first extension tab 31b and the second extension tab 31c.

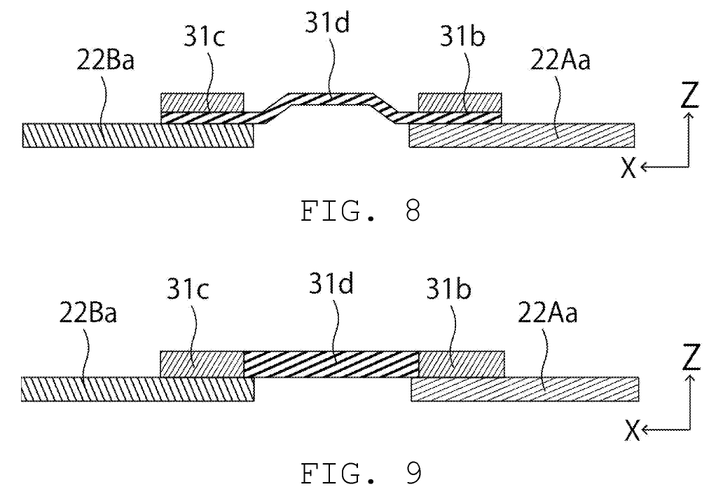

FIG. 9 is a schematic diagram showing a cross-sectional diagram of the configuration of the semiconductor device 100 using a member provided with the first bridge member 31d on the output terminal 31 before bonding. The first bridge member 31d is plate-shaped. When the member provided with the first bridge member 31d on the output terminal 31 is used before bonding, the element primarily constituting the plane member 31a is preferably the same as the element primarily constituting the first bridge member 31d. Preferably, Cu is the element primarily constituting the plane member 31a and Cu the element primarily constituting the first bridge member 31d.

When the member provided with the first bridge member 31d on the output terminal 31 is used before bonding, the output terminal 31 is positioned on the first output wiring 22Aa and the second output wiring 22Ba, and ultrasonic bonding is performed to join the first output wiring 22Aa and the second output wiring 22Ba to the output terminal 31. Applying ultrasonic waves and pressure eliminates gaps between the first extension tab 31b and the first output wiring 22Aa, and between the second extension tab 31c and the second output wiring 22Ba. As a result, the output terminal with the first bridge member 31d is firmly joined to the first output wiring 22Aa and the second output wiring 22Ba.

From the viewpoint of reducing inductance between the sources, the maximum height (maximum distance) H3 (height of the first bridge member 31d from the surface of the first output wiring 22Aa facing the output terminal 31) between the surface of the first output wiring 22Aa facing the output terminal 31 and the bottom surface of the first bridge member 31d is preferably lower than the height H1 of the first extension tab 31b, which is the distance from the surface of the first output wiring 22Aa facing the output terminal 31 to the bottom surface of the plane member 31a. H3 is preferably 0% or more and 50% or less of H1, and more preferably 0% or more and 30% or less. H3 is preferably greater than 0% and 50% or less of H1, and more preferably greater than 0% and 30% or less.

From the viewpoint of reducing inductance between the sources, the maximum height (maximum distance) H4 (height of the first bridge member 31d from the surface of the second output wiring 22Ba facing the output terminal 31) between the surface of the second output wiring 22Ba facing the output terminal 31 and the bottom surface of the first bridge member 31d is preferably lower than the height H2 of the second extension tab 31c, which is the distance from the surface of the second output wiring 22Ba facing the output terminal 31to the bottom surface of the plane member 31a. H4 is preferably 0% or more and 50% or less of H2, and more preferably 0% or more and 30% or less. H4 is preferably greater than 0% and 50% or less of H2, and more preferably greater than 0% and 30% or less.

H3 is preferably 500 μm or less, and more preferably 100 μm or less. H3 is preferably 0 μm or more and 500 μm or less, and more preferably 0 μm or more and 100 μm or less. H3 is preferably 50 μm or more and 500 μm or less, and more preferably 50 μm or more and 100 μm or less. For example, since the height of a bonding wire to be mounted on a circuit board is 1 mm or more (about 3 mm), the first bridge member 31d contributes to low-inductance source connection.

H4 is preferably 500 μm or less, and more preferably 100 μm or less. H4 is preferably 0 μm or more and 500 μm or less, and more preferably 0 μm or more and 100 μm or less. H4 is preferably 50 μm or more and 500 μm or less, and more preferably 50 μm or more and 100 μm or less. For example, since the height of a bonding wire to be mounted on a circuit board is 1 mm or more (about 3 mm), the first bridge member 31d contributes to low-inductance source connection.

### Second Embodiment

A second embodiment relates to a semiconductor device includes a first circuit board having a plurality of first semiconductor elements, a second circuit board having a plurality of second semiconductor elements, a third circuit board having a plurality of third semiconductor elements, a fourth circuit board having a plurality of fourth semiconductor elements, and an output terminal connecting a first output wiring of the first circuit board and a second output wiring of the second circuit board, and having a plane member, a first extension tab, a second extension tab, a third extension tab, a fourth extension tab, a first bridge member, and a second bridge member. The first extension tab is connected to the first output wiring of the first circuit board. The second extension tab is connected to a second output wiring of the second circuit board. The first extension tab and the second extension tab are connected by the first bridge member. The third extension tab and the fourth extension tab are connected by the second bridge member.

FIG. 10 is a top view schematic diagram illustrating a semiconductor device 200 of the second embodiment. FIG. 11 is a perspective schematic diagram illustrating the semiconductor device 200 according to the second embodiment. In the diagram of FIG. 10 members such as gate terminals are omitted. In the diagram of FIG. 10, some members (for example, terminals) are partially illustrated.

The semiconductor device 200 according to the second embodiment is a modification of the semiconductor device 100 of the first embodiment.

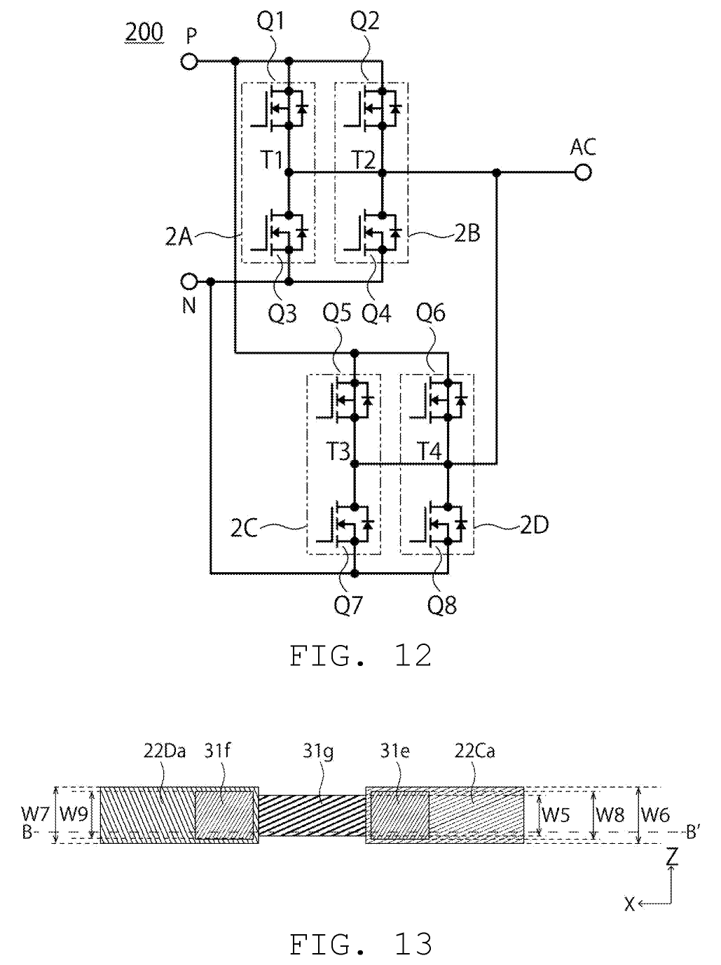

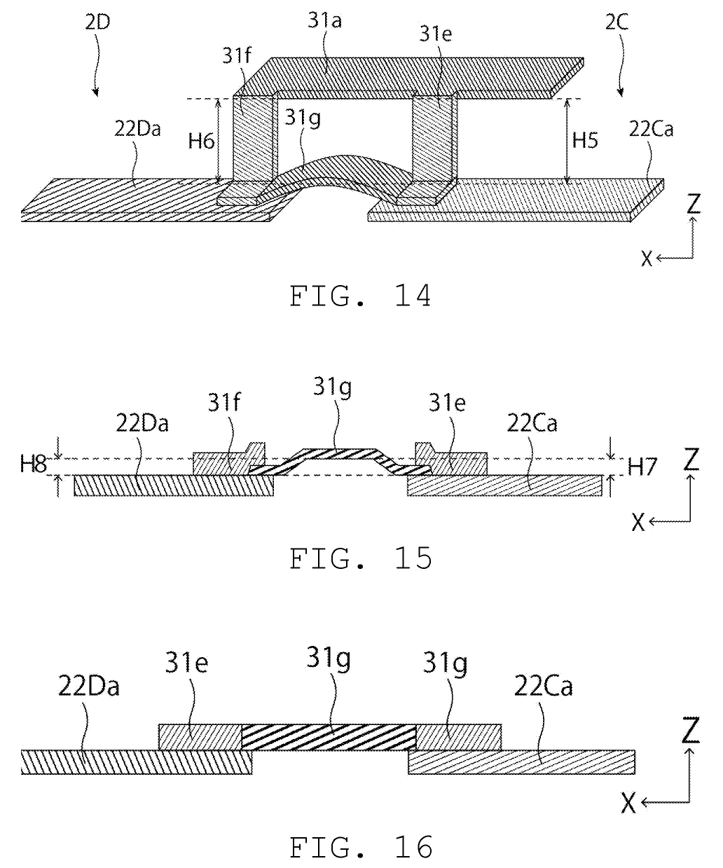

FIG. 12 is a equivalent circuit diagram of the semiconductor device 200 according to the second embodiment. FIGS. 13, 14, 15, and 16 are diagrams illustrating a portion of the semiconductor device 200 according to the second embodiment with some members removed. FIGS. 15 and 16 are cross-sectional views along line BB' in FIG. 13.

The semiconductor device 200 according to the second embodiment is a modification of the semiconductor device 100 of the first embodiment. Overlapping descriptions between the first embodiment and the second embodiment are omitted.

FIG. 12 is an equivalent circuit diagram of the semiconductor device 200 using MOSFETs for semiconductor elements Q1 to Q8.

The semiconductor device 200 includes a plurality of high-side semiconductor elements (the first semiconductor element Q1, the second semiconductor element Q2, a third semiconductor elements Q5, and a fourth semiconductor elements Q6) and a plurality of low-side semiconductor elements (the semiconductor element Q3, the semiconductor element Q4, a semiconductor element Q7, and a semiconductor element Q8). FIG. 10 illustrates an example configuration in which the first semiconductor element Q1, the second semiconductor element Q2, the semiconductor element Q3, and the semiconductor element Q4 each comprise three semiconductor elements.

The first circuit board 2A and the third circuit board 2C are similar members arranged symmetrically. The third circuit board 2C corresponds to the first circuit board 2A. The third semiconductor element Q5 corresponds to the first semiconductor element Q1. The semiconductor element Q7 corresponds to the semiconductor element Q3. A wiring 4C corresponds to the wiring 4A. A wiring 5C corresponds to the wiring 5A. A conductive layer 21C corresponds to the conductive layer 21A. A conductive layer 22C corresponds to the conductive layer 22A. A conductive layer 23C corresponds to the conductive layer 23A. A conductive layer 24C corresponds to the conductive layer 24A. A conductive layer 25C corresponds to the conductive layer 25A. The third output wiring 22Ca corresponds to the first output wiring 22Aa. A third power wiring 21Ca corresponds to the first power wiring 21Aa.

Regarding the third circuit board 2C and members formed on it, some explanations are omitted because they overlap with the explanations regarding the first circuit board 2A and members formed on it.

The second circuit board 2B and the fourth circuit board 2D are similar members arranged symmetrically. The fourth circuit board 2D corresponds to the second circuit board 2B. The fourth semiconductor element Q6 corresponds to the second semiconductor element Q2. The semiconductor element Q8 corresponds to the semiconductor element Q4. A wiring 4D corresponds to the wiring 4B. A wiring 5D corresponds to the wiring 5B. A conductive layer 21D corresponds to the conductive layer 21B. A conductive layer 22D corresponds to the conductive layer 22B. A conductive layer 23D corresponds to the conductive layer 23B. A conductive layer 24D corresponds to the conductive layer 24B. A conductive layer 25D corresponds to the conductive layer 25B. The fourth output wiring 22Da corresponds to the second output wiring 22Ba. A fourth power wiring 21Da corresponds to the second power wiring 21Ba.

The third semiconductor element Q5 is provided on the third circuit board 2C. The fourth semiconductor element Q6 is provided on the fourth circuit board 2D.

Regarding the fourth circuit board 2D and members formed on it, some explanations are omitted because they overlap with the explanations regarding the second circuit board 2B and members formed on it.

The output terminal 31 connects the first output wiring 22Aa, the second output wiring 22Ba, the third output wiring 22Ca, and the fourth output wiring 22Da.

As shown in FIG. 11, the output terminal 31 includes the plane member 31a which is not in direct contact with the second bridge member 31g, the first extension tab 31b, the second extension tab 31c, the first bridge member 31d, the third extension tab 31e, the fourth extension tab 31f, and the second bridge member 31g. The output terminal 31 has an opening such as a screw hole in a portion to be connected to the outside. This opening is electrically connected to an external terminal not shown in the figure.

The plane member 31a is connected to the first extension tab 31b, the second extension tab 31c, the third extension tab 31e, and the fourth extension tab 31f. The first extension tab 31b, the second extension tab 31c, the third extension tab 31e, and the fourth extension tab 31f extend from the plane member 31a.

The third extension tab 31e is connected to the third output wiring 22ACa. Preferably, the third extension tab 31e is in direct contact with the third output wiring 22Ca. Two bend structures are included between the plane member 31a and the connection portion of the third extension tab 31e and the third output wiring 22Ca.

The fourth extension tab 31f is connected to the fourth output wiring 22Da. Preferably, the fourth extension tab 31f is in direct contact with the fourth output wiring 22Da. Two bend structures are included between the plane member 31a and the connection portion of the fourth extension tab 31f and the fourth output wiring 22Da.

The second bridge member 31g connects the third extension tab 31e and the fourth extension tab 31f. The second bridge member 31g is provided between the third extension tab 31e and the fourth extension tab 31f. Preferably, the second bridge member 31g is electrically and directly connected to the third extension tab 31e and the fourth extension tab 31f. The second bridge member 31g electrically connects T3 and T4 in the equivalent circuit diagram shown in FIG. 12.

The third extension tab 31e has a bent shape at its connection portion with the plane member 31a and its connection portion with the third output wiring 22Ca. The fourth extension tab 31f has a bent shape at its connection portion with the plane member 31a and its connection portion with the fourth output wiring 22Da. It is preferable that the route from the third output wiring 22Ca through the third extension tab 31e to the fourth output wiring 22Da does not pass through the bent portions of the third extension tab 31e and the fourth extension tab 31f.

The second bridge member 31g is preferably a single conductor connecting the third extension tab 31e and the fourth extension tab 31f. For example, the second bridge member 31g is preferably a flat plate-like or a partially curved ribbon-like conductor. When the first bridge member 31d is plate-like, it is preferable that the second bridge member 31g is also plate-like. When the first bridge member 31d is ribbon-like, it is preferable that the second bridge member 31g is also ribbon-like.

The second bridge member 31g is preferably not divided into two or more conductors connecting the third extension tab 31e and the fourth extension tab 31f.

Since the second bridge member 31g is not a thin wire such as a bonding wire, it is less likely to be cut when fixing the output terminal 31 to the third circuit board 2C and the fourth circuit board D, resulting in higher reliability.

Similar to the first bridge member 31d, the second bridge member 31g connects the third extension tab 31e and the fourth extension tab 31f with low inductance, enabling a low-inductance connection between the source of the third semiconductor element Q5 and the source of the fourth semiconductor element Q6. The semiconductor device 200 can prevent oscillations of the semiconductor elements mounted on the third circuit board 2C and the fourth circuit board 2D similarly to the oscillations of the semiconductor elements mounted on the first circuit board 2A and the second circuit board 2B.

The first terminal 32 is provided on the first circuit board 2A, the second circuit board 2B, the third circuit board 2C, and the fourth circuit board 2D. The first terminal 32 extends across the first circuit board 2A, the second circuit board 2B, the third circuit board 2C, and the fourth circuit board 2D. The first terminal 32 connects the first power wiring 21Aa, the second power wiring 21Ba, the third power wiring 21Ca, and the fourth power wiring 21Da. The first terminal 32 electrically connects the first power wiring 21Aa, the second power wiring 21Ba, the third power wiring 21Ca, and the fourth power wiring 21Da. The first terminal 32 is preferably in direct electrical contact with the first power wiring 21Aa, the second power wiring 21Ba, the third power wiring 21Ca, and the fourth power wiring 21Da.

The second terminal 33 is provided on the first circuit board 2A, the second circuit board 2B, the third circuit board 2C, and the fourth circuit board 2D. The second terminal 33 extends across the first circuit board 2A, the second circuit board 2B, the third circuit board 2C, and the fourth circuit board 2D. The second terminal 33 connects the conductive layer 23A, the conductive layer 23B, the conductive layer 23C, and the conductive layer 23D. The second terminal 33 electrically connects the conductive layer 23A, the conductive layer 23B, the conductive layer 23C, and the conductive layer 23D. The second terminal 33 is preferably in direct electrical contact with the conductive layer 23A, the conductive layer 23B, the conductive layer 23C, and the conductive layer 23D.

FIG. 13 is a schematic diagram showing the width of each member. The wiring width of the second bridge member 31g is represented by W5. The wiring width of the third output wiring 22Ca is represented by W6. The wiring width of the fourth output wiring 22Da is represented by W7. The wiring width of the third extension tab 31e is represented by W8. The wiring width of the fourth extension tab 31f is represented by W9.

The wiring width W5 of the second bridge member 31g is the length of the second bridge member 31g in a direction perpendicular to the direction from the third extension tab 31e to the fourth extension tab 31f as viewed from above, as shown in FIG. 2. The wiring width W5 does not consider the portion where the third extension tab 31e and the second bridge member 31g overlap in the Z direction.

The maximum value of the wiring width W5 of the second bridge member 31g is preferably 100% or more and 120% or less than the average value of the wiring width W5.

The minimum value of the wiring width W5 of the second bridge member 31g is preferably 80% or more and 100% or less than the average value of the wiring width W5.

The wiring width W6 of the third output wiring 22Ca is the average width of the third output wiring 22Ca, including the portion where the third output wiring 22Ca and the third extension tab 31e are connected.

From the viewpoint of lowering the inductance between sources, the wiring width W5 of the second bridge member 31g is preferably 60% or more and 100% or less than the wiring width W6 of the third output wiring 22Ca, and more preferably 65% or more and 95% or less.

The wiring width W7 of the fourth output wiring 22Da is the average width of the fourth output wiring 22Da, including the portion where the fourth output wiring 22Da and the fourth extension tab 31f are connected.

From the viewpoint of lowering the inductance between sources, the wiring width W5 of the second bridge member 31g is preferably 60% or more and 100% or less than the wiring width W7 of the fourth output wiring 22Da, and more preferably 65% or more and 95% or less.

From the viewpoint of lowering the inductance between sources, the wiring width W8 of the third extension tab 31e is preferably 70% or more and 100% or less than the wiring width W6, and more preferably 75% or more and 95% or less.

From the viewpoint of lowering the inductance between sources, the wiring width W9 of the fourth extension tab 31f is preferably 70% or more and 100% or less than the wiring width W7, and more preferably 75% or more and 95% or less.

From the viewpoint of lowering the inductance between sources, the wiring width W5 of the second bridge member 31g is preferably 60% or more and 100% or less than the wiring width W6 of the third output wiring 22Ca and 60% or more and 100% or less than the wiring width W7 of the fourth output wiring 22Da, and more preferably 65% or more and 95% or less than the wiring width W6 of the third output wiring 22Ca and 65% or more and 95% or less than the wiring width W7 of the fourth output wiring 22Da.

Preferably, the longitudinal direction of the second bridge member 31g is directed from the third circuit board 2C to the fourth circuit board 2D. Preferably, the width direction of the second bridge member 31g is the same as the width direction of the third output wiring 22Ca. Preferably, the width direction of the second bridge member 31g is the same as the width direction of the fourth output wiring 22Da. When the width direction of the fourth output wiring 22Da is significantly different, the wiring length will become longer, which is undesirable. Preferably, the width direction of the second bridge member 31g and the width direction of the third output wiring 22Ca are generally consistent. The angle difference between the width direction of the second bridge member 31g and the width direction of the third output wiring 22Ca is preferably 0 degrees or more and 10 degrees or less, and more preferably 0 degrees or more and 5 degrees or less. As for the parallelism of other members, an angle deviation is allowed, and the angle difference is preferably 0 degrees or more and 10 degrees or less, and more preferably 0 degrees or more and 5 degrees or less.

FIG. 15 is a perspective cross-sectional diagram of a configuration of a portion where the second bridge member 31g uses a ribbon such as aluminum. The second bridge member 31g is ribbon-shaped. The shape of the output terminal 31 when using a ribbon is not limited to the shapes shown in FIGS. 7 and 8. The shape of the output terminal 31 when using a ribbon can be changed depending on the thickness of the members and the conditions during ultrasonic bonding. When a ribbon is used for the second bridge member 31g, it is preferable that the element mainly constituting the plane member 31a is different from the element mainly constituting the second bridge member 31g (the metal element having the highest ratio contained in the second bridge member 31g). It is preferable that the element mainly constituting the plane member 31a is Cu, and the element mainly constituting the second bridge member 31g is an element (for example, Al) other than Cu.

The output terminal 31 is arranged without the second bridge member 31g on the ribbon, and ultrasonic bonding is performed to integrate the ribbon with the output terminal 31. Then, the third output wiring 22Ca is joined to the output terminal 31, and the fourth output wiring 22Da is also joined to the output terminal 31. After joining, the non-joined portion of the ribbon forms the second bridge member 31g. By applying ultrasonic waves and pressure, the gaps between the third extension tab 31e and the third output wiring 22Ca with the ribbon sandwiched therebetween, and the gaps between the fourth extension tab 31f and the fourth output wiring 22Da with the ribbon sandwiched therebetween are eliminated, and the output terminal having the second bridge member 31g is firmly joined to the third output wiring 22Ca and the fourth output wiring 22Da.

During ultrasonic bonding, pressure is applied to the third extension tab 31e and the fourth extension tab 31f using a capillary on the portion where they overlap with the ribbon, and these tabs are partially deformed to perform joining. It is preferable that the thickness of the second bridge member 31g (ribbon thickness) is about the same as the depth at which the capillary is pressed against the members and sinks in. The thickness of the second bridge member 31g (ribbon thickness) is preferably 70% or more and 130% or less of the thickness of the non-joined portions of the third extension tab 31e and the fourth extension tab 31f, and more preferably 85% or more and 115% or less.

FIG. 16 is a perspective diagram showing a cross-sectional view of the configuration before bonding, in which a member on which the second bridge member 31g is provided is used for the output terminal 31. The second bridge member 31g is plate-shaped. When a member on which the second bridge member 31g is provided beforehand is used for the output terminal 31, it is preferable that the element mainly constituting the plane member 31a and the element mainly constituting the second bridge member 31g are the same. It is preferable that the element mainly constituting the plane member 31a is Cu and the element mainly constituting the second bridge member 31g is also Cu.

When a member on which the second bridge member 31g is provided beforehand is used for the output terminal 31, the output terminal 31 is arranged on the third output wiring 22Ca and the fourth output wiring 22Da, and ultrasonic bonding is performed to join the third output wiring 22Ca and the fourth output wiring 22Da with the output terminal 31. By applying ultrasonic waves and pressure, the gaps between the third extension tab 31e and the third output wiring 22Ca and between the fourth extension tab 31f and the fourth output wiring 22Da are eliminated when sandwiched by a ribbon, and the output terminal having the second bridge member 31g is firmly joined to the third output wiring 22Ca and the fourth output wiring 22Da.

It is preferable that the element mainly constituting the first bridge member 31d is the same as the element mainly constituting the second bridge member 31g.

There is preferably no bridge portion between the first extension tab 31b and the third extension tab 31e. The first extension tab 31b and the third extension tab 31e are electrically connected without a bridge member.

There is preferably no bridge portion between the second extension tab 31c and the fourth extension tab 31f. The second extension tab 31c and the fourth extension tab 31f are electrically connected without a bridge member.

As shown in FIGS. 14 and 15, from the viewpoint of reducing inductance between sources, the maximum height H7 (height of the second bridge member 31g from the surface facing the output terminal 31 side of the third output wiring 22Ca) to the bottom surface of the plane member 31a is preferably lower than the height H5 of the third extension tab 31e, which is the distance from the surface facing the output terminal 31 side of the third output wiring 22Ca to the bottom surface of the plane member 31a. H7 is preferably 0% or more and 50% or less of H5, and more preferably 0% or more and 30% or less. H7 is preferably greater than 0% and 50% or less of H5, and more preferably greater than 0% and 30% or less.

H7 is preferably 500 μm or less, and more preferably 100 μm or less. H7 is preferably 0 μm or more and 500 μm or less, and more preferably 0 μm or more and 100 μm or less. For example, since the height of a bonding wire placed on a circuit board is 1 mm or more (about 3 mm), the second bridge part 2g contributes to low-inductance source interconnections.

From the viewpoint of reducing inductance between sources, the maximum height (maximum distance) H8 (height of the second bridge member 31g from the surface of the fourth output wiring 22Da facing the output terminal 31 side ) between the surface facing the fourth output wiring 22Da of the output terminal 31 and the bottom surface of the second bridge member 31g is preferably lower than the height H6 of the fourth extension tab 31f,which is the distance from the surface of the fourth output wiring 22Da facing the output terminal 31 to the bottom surface of the plane member 31a. H8 is preferably 0% or more and 50% or less of H6, and more preferably 0% or more and 30% or less. H8 is preferably greater than 0% and 50% or less of H6, and more preferably greater than 0% and 30% or less.

H7 is preferably 500 μm or less, and more preferably 100 μm or less. H7 is preferably 0 μm or more and 500 μm or less, and more preferably 0 μm or more and 100 μm or less. H7 is preferably 50 μm or more and 500 μm or less, and more preferably 50 μm or more and 100 μm or less. For example, since the height of a bonding wire placed on a circuit board is 1 mm or more (about 3 mm), the second bridge part 2g contributes to low-inductance source interconnections.

H8 is preferably 500 μm or less, and more preferably 100 μm or less. H8 is preferably 0 μm or more and 500 μm or less, and more preferably 0 μm or more and 100 μm or less. H8 is preferably 50 μm or more and 500 μm or less, and more preferably 50 μm or more and 100 μm or less. For example, since the height of a bonding wire placed on a circuit board is 1 mm or more (about 3 mm), the second bridge member 31g contributes to low-inductance source interconnections.

In the specification, some elements are represented only by chemical symbols for elements.

Hereinafter, technical clauses of embodiments are additionally noted.

Clause 1.

A semiconductor device comprising:
a first circuit board comprising a plurality of first semiconductor elements;
a second circuit board comprising a plurality of second semiconductor elements; and
an output terminal comprising a plane member, a
first extension tab, a second extension tab and a first bridge member, wherein the first extension tab is connected to a first output wiring of the first circuit board,
the second extension tab is connected to a second output wiring of the second circuit board, and
the first extension tab and the second extension tab are connected by the first bridge member.

Clause 2.

The semiconductor device according to clause 1, wherein

the first extension tab is in direct contact with the first bridge member,

the second extension tab is in direct contact with the first bridge member,

the plane member is electrically connected to the first bridge member, and

the plane member is not in direct contact with the first bridge member.

Clause 3.

The semiconductor device according to clause 1 or 2, wherein

a width W0 of the first bridge member is 65% or more and 95% or less of a width W1 of the first output wiring,

the width W1 is the average width of the first output wiring, including the portion where the first output wiring and the first extension tab are connected,

a width W0 of the first bridge member is 65% or more and 95% or less of a width W2 of the second output wiring, and

the width W2 is the average width of the second output wiring, including the portion where the second output wiring and the second extension tab are connected.

Clause 4.

The semiconductor device according to any one of clauses 1 to 3, wherein

the first bridge member is a single conductor.

Clause 5.

The semiconductor device according to any one of clauses 1 to 4, wherein

the first bridge member is not divided into two or more conductors.

Clause 6.

The semiconductor device according to clause 3, wherein

a width direction of the first bridge member is in the same direction as a width direction of the first output wiring, and

the width direction of the first bridge member is in the same direction as a width direction of the second output wiring.

Clause 7. The semiconductor device according to clause 3 or 6, wherein

a width direction of the first extension tab is along with a width direction of the width W1,

a width direction of the second extension tab is along with a width direction of the width W2,

a wiring width W3 of the first extension tab is 75% or more and 95% or less of the width W1, and

a wiring width W4 of the first extension tab is 75% or more and 95% or less of the width W2.

Clause 8.

The semiconductor device according to any one of clauses 1 to 7, wherein

a longitudinal direction of the first bridge member is in a direction from the first circuit board to the second circuit board.

Clause 9.

The semiconductor device according to any one of clauses 1 to 8 further comprising:
a third circuit board comprising a plurality of third semiconductor elements; and
a fourth circuit board comprising a plurality of fourth semiconductor elements, wherein the output terminal further comprising a third extension tab, a fourth extension tab, and a second bridge member, wherein
the output terminal connects a third output wiring of the third circuit board and the fourth output wiring of the fourth circuit board,
the third extension tab connects the third output wiring,
the fourth extension tab connects the fourth output wiring, and
the third extension tab and the fourth extension tab are connected by the second bridge member.

Clause 10.

The semiconductor device according to clause 9, wherein

the third extension tab is in direct contact with the second bridge member,

the fourth extension tab is in direct contact with the second bridge member,

the plane member is electrically connected to the second bridge member, and

the plane member is not in direct contact with the second bridge member.

Clause 11.

The semiconductor device according to clause 9, wherein

a width W5 of the second bridge member is 65% or more and 95% or less of a width W6 of the third output wiring,

the width W6 is an average width of the third output wiring where the third output wiring and the third extension tab are connected,

a width W5 of the second bridge member is 65% or more and 95% or less of a width W7 of the third output wiring,

the width W7 is an average width of the fourth output wiring where the fourth output wiring and the fourth extension tab are connected,

a width direction of the second bridge member is in the same direction as a width direction of the width W6,

the width direction of the second bridge member is in the same direction as a width direction of the width W7,

a width direction of the third extension tab is in the same direction as a width direction of the width W6,

a width direction of the fourth extension tab is in the same direction as a width direction of the width W7,

a width W8 of the third extension tab is 65% or more and 95% or less of a width W6, and

a width W9 of the fourth extension tab is 65% or more and 95% or less of a width W7.

Clause 12.

The semiconductor device according to clause 9 or 10, wherein

the second bridge member is a single conductor, and

the second bridge member is not divided into two or more conductors.

Clause 13.

The semiconductor device according to any one of clauses 1 to 12, wherein

an element primarily constituting the plane member is different from an element primarily constituting the first bridge member or/and an element primarily constituting the second bridge member.

Clause 14.

The semiconductor device according to any one of clauses 1 to 13, wherein

an element primarily constituting the plane member is the same as an element primarily constituting the first bridge member or/and an element primarily constituting the second bridge member.

Clause 15.

The semiconductor device according to any one of clauses 1 to 14, wherein

a maximum height H3 between a surface of the first output wiring facing the output terminal and a bottom surface of the

first bridge member is 0% or more and 50% or less of a height H1 of the first extension tab, and

a maximum height H4 between a surface of the second output wiring facing the output terminal and a bottom surface of the first bridge member is 0% or more and 50% or less of a height H2 of the second extension tab.

Clause 16.

The semiconductor device according to clause 9 or 11, wherein

a maximum height H7 between a surface of the third output wiring facing the output terminal and a bottom surface of the second bridge member is 0% or more and 50% or less of a height H5 of the third extension tab, and

a maximum height H8 between a surface of the fourth output wiring facing the output terminal and a bottom surface of the second bridge member is 0% or more and 50% or less of a height H6 of the fourth extension tab.

Clause 17.

The semiconductor device according to any one of clauses 1 to 16, wherein

a maximum height H3 between a surface of the first output wiring facing the output terminal and a bottom surface of the first bridge member is greater than 0% and 30% or less of a height H1 of the first extension tab, and

a maximum height H4 between a surface of the second output wiring facing the output terminal and a bottom surface of the first bridge member is greater than 0% and 30% or less of a height H2 of the second extension tab.

Clause 18.

The semiconductor device according to clause 9 or 11, wherein

a maximum height H7 between a surface of the third output wiring facing the output terminal and a bottom surface of the second bridge member is greater than 0% and 30% or less of a height H5 of the third extension tab, and

a maximum height H8 between a surface of the fourth output wiring facing the output terminal and a bottom surface of the second bridge member is greater than 0% and 30% or less of a height H6 of the fourth extension tab.

Clause 19.

The semiconductor device according to any one of clauses 1 to 18, wherein

an angle difference between the width direction of the first bridge member and a width direction of the first output wiring is 0° or more and 10° or less, and

an angle difference between the width direction of the second bridge member and a width direction of the third output wiring is 0° or more and 10° or less.

Clause 20.

The semiconductor device according to any one of clauses 1 to 19, wherein

a thickness of the first bridge member is 70% or more and 130% or less of a thickness of a non-joined portions of the first extension tab and the second extension tab, and

a thickness of the second bridge member is 70% or more and 130% or less of a thickness of a non-joined portions of the third extension tab and the fourth extension tab.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first circuit board comprising a plurality of first semiconductor elements;
a second circuit board comprising a plurality of second semiconductor elements; and
an output terminal comprising a plane member, a first extension tab, a second extension tab and a first bridge member, wherein
the first extension tab is connected to a first output wiring of the first circuit board,
the second extension tab is connected to a second output wiring of the second circuit board, and
the first extension tab and the second extension tab are connected by the first bridge member.

2. The semiconductor device according to claim 1, wherein
the first extension tab is in direct contact with the first bridge member,
the second extension tab is in direct contact with the first bridge member,
the plane member is electrically connected to the first bridge member, and
the plane member is not in direct contact with the first bridge member.

3. The semiconductor device according to claim 1, wherein
a width W0 of the first bridge member is 65% or more and 95% or less of a width W1 of the first output wiring,
the width W1 is the average width of the first output wiring, including the portion where the first output wiring and the first extension tab are connected,
a width W0 of the first bridge member is 65% or more and 95% or less of a width W2 of the second output wiring, and
the width W2 is the average width of the second output wiring, including the portion where the second output wiring and the second extension tab are connected.

4. The semiconductor device according to claim 1, wherein
the first bridge member is a single conductor.

5. The semiconductor device according to claim 1, wherein
the first bridge member is not divided into two or more conductors.

6. The semiconductor device according to claim 1, wherein
a width direction of the first bridge member is in the same direction as a width direction of the first output wiring, and
the width direction of the first bridge member is in the same direction as a width direction of the second output wiring.

7. The semiconductor device according to claim 3, wherein
a width direction of the first extension tab is along with a width direction of the width W1,
a width direction of the second extension tab is along with a width direction of the width W2,
a wiring width W3 of the first extension tab is 75% or more and 95% or less of the width W1, and
a wiring width W4 of the first extension tab is 75% or more and 95% or less of the width W2.

8. The semiconductor device according to claim 1, wherein
a longitudinal direction of the first bridge member is in a direction from the first circuit board to the second circuit board.

9. The semiconductor device according to claim 1 further comprising:
a third circuit board comprising a plurality of third semiconductor elements; and
a fourth circuit board comprising a plurality of fourth semiconductor elements, wherein
the output terminal further comprising a third extension tab, a fourth extension tab, and a second bridge member, wherein
the output terminal connects a third output wiring of the third circuit board and the fourth output wiring of the fourth circuit board,
the third extension tab connects the third output wiring,
the fourth extension tab connects the fourth output wiring, and
the third extension tab and the fourth extension tab are connected by the second bridge member.

10. The semiconductor device according to claim 9, wherein
the third extension tab is in direct contact with the second bridge member,
the fourth extension tab is in direct contact with the second bridge member,
the plane member is electrically connected to the second bridge member, and
the plane member is not in direct contact with the second bridge member.

11. The semiconductor device according to claim 9, wherein
a width W5 of the second bridge member is 65% or more and 95% or less of a width W6 of the third output wiring,
the width W6 is an average width of the third output wiring where the third output wiring and the third extension tab are connected,
a width W5 of the second bridge member is 65% or more and 95% or less of a width W7 of the third output wiring,
the width W7 is an average width of the fourth output wiring where the fourth output wiring and the fourth extension tab are connected,
a width direction of the second bridge member is in the same direction as a width direction of the width W6,
the width direction of the second bridge member is in the same direction as a width direction of the width W7,
a width direction of the third extension tab is in the same direction as a width direction of the width W6,
a width direction of the fourth extension tab is in the same direction as a width direction of the width W7,
a width W8 of the third extension tab is 65% or more and 95% or less of a width W6, and
a width W9 of the fourth extension tab is 65% or more and 95% or less of a width W7.

12. The semiconductor device according to claim 9, wherein
the second bridge member is a single conductor, and
the second bridge member is not divided into two or more conductors.

13. The semiconductor device according to claim 9, wherein
an element primarily constituting the plane member is different from an element primarily constituting the first bridge member or/and an element primarily constituting the second bridge member.

14. The semiconductor device according to claim 9, wherein
an element primarily constituting the plane member is the same as an element primarily constituting the first bridge member or/and an element primarily constituting the second bridge member.

15. The semiconductor device according to claim 1, wherein
a maximum height H3 between a surface of the first output wiring facing the output terminal and a bottom surface of the first bridge member is 0% or more and 50% or less of a height H1 of the first extension tab, and
a maximum height H4 between a surface of the second output wiring facing the output terminal and a bottom surface of the first bridge member is 0% or more and 50% or less of a height H2 of the second extension tab.

16. The semiconductor device according to claim 9, wherein
a maximum height H7 between a surface of the third output wiring facing the output terminal and a bottom surface of the second bridge member is 0% or more and 50% or less of a height H5 of the third extension tab, and
a maximum height H8 between a surface of the fourth output wiring facing the output terminal and a bottom surface of the second bridge member is 0% or more and 50% or less of a height H6 of the fourth extension tab.

17. The semiconductor device according to claim 1, wherein
a maximum height H3 between a surface of the first output wiring facing the output terminal and a bottom surface of the first bridge member is greater than 0% and 30% or less of a height H1 of the first extension tab, and
a maximum height H4 between a surface of the second output wiring facing the output terminal and a bottom surface of the first bridge member is greater than 0% and 30% or less of a height H2 of the second extension tab.

18. The semiconductor device according to claim 9, wherein
a maximum height H7 between a surface of the third output wiring facing the output terminal and a bottom surface of the second bridge member is greater than 0% and 30% or less of a height H5 of the third extension tab, and
a maximum height H8 between a surface of the fourth output wiring facing the output terminal and a bottom surface of the second bridge member is greater than 0% and 30% or less of a height H6 of the fourth extension tab.

19. The semiconductor device according to claim 9, wherein
an angle difference between the width direction of the first bridge member and a width direction of the first output wiring is 0° or more and 10° or less, and
an angle difference between the width direction of the second bridge member and a width direction of the third output wiring is 0° or more and 10° or less.

20. The semiconductor device according to claim 9, wherein
a thickness of the first bridge member is 70% or more and 130% or less of a thickness of a non-joined portions of the first extension tab and the second extension tab, and
a thickness of the second bridge member is 70% or more and 130% or less of a thickness of a non-joined portions of the third extension tab and the fourth extension tab.
